(19) United States
(12) Patent Application Publication
(10) Pub. No.: US 2019/0104610 A1
(43) Pub. Date: Apr. 4, 2019

(54) SUBSTRATE ARCHITECTURE FOR SOLDER JOINT RELIABILTY IN MICROELECTRONIC PACKAGE STRUCTURES AND METHODS OF FORMING THE SAME

(71) Applicant: Intel Corporation, Santa Clara, CA (US)

(72) Inventors: Robert Nickerson, Chandler, AZ (US); Nitin Deshpande, Chandler, AZ (US); Omkar Karhade, Chandler, AZ (US); Thomas De Bonis, Tempe, AZ (US)

(73) Assignee: Intel Corporation, Santa Clara, CA (US)

(21) Appl. No.: 15/720,488

(22) Filed: Sep. 29, 2017

(51) Int. Cl. H05K 1/02; H05K 1/14; H05K 3/00

(52) U.S. Cl. CPC H05K 1/0256; H05K 3/0026; H05K 3/0044; H05K 1/144

(57) ABSTRACT

Methods/structures of joining package structures are described. Those methods/structures may include a first substrate comprising a first die, wherein an underfill material is disposed on a first surface of the first substrate adjacent the first die; and a second substrate disposed on the first substrate, wherein the second substrate comprises at least one opening disposed over the first die, wherein the at least one opening is at least partially filled with the underfill material.

### BACKGROUND

The assembly processes utilized in the assembly of microelectronic package structures, such as package on package (PoP) structures, for example, can be a fabrication challenge for electronic manufacturers. Such issues as package warpage and poor solder joint formation can impact package performance.

### BRIEF DESCRIPTION OF THE DRAWINGS

While the specification concludes with claims particularly pointing out and distinctly claiming certain embodiments, the advantages of these embodiments can be more readily ascertained from the following description when read in conjunction with the accompanying drawings in which:

FIG. 1 represents a cross-sectional view of a package structure according to embodiments.

FIGS. 2a-2e represents cross-sectional views of methods of forming package structures according to embodiments. FIG. 2f depicts a top view of package structures according to embodiments.

FIG. 3 represents a cross-sectional view of package assembly according to embodiments.

FIG. 4 represents a flow chart of a method of forming package structures according to embodiments.

FIG. 5 represents a schematic of a computing device according to embodiments.

### DETAILED DESCRIPTION

In the following detailed description, reference is made to the accompanying drawings that show, by way of illustration, specific embodiments in which the methods and structures may be practiced. These embodiments are described in sufficient detail to enable those skilled in the art to practice the embodiments. It is to be understood that the various embodiments, although different, are not necessarily mutually exclusive. For example, a particular feature, structure, or characteristic described herein, in connection with one embodiment, may be implemented within other embodiments without departing from the spirit and scope of the embodiments. In addition, it is to be understood that the location or arrangement of individual elements within each disclosed embodiment may be modified without departing from the spirit and scope of the embodiments.

The following detailed description is, therefore, not to be taken in a limiting sense, and the scope of the embodiments is defined only by the appended claims, appropriately interpreted, along with the full range of equivalents to which the claims are entitled. In the drawings, like numerals may refer to the same or similar functionality throughout the several views. The terms “over”, “to”, “between” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers. Layers and/or structures “adjacent” to one another may or may not have intervening structures/layers between them. A layer(s)/structure(s) that is/are directly on/directly in contact with another layer(s)/structure(s) may have no intervening layer(s)/structure(s) between them.

Various implementations of the embodiments herein may be formed or carried out on a substrate, such as a package substrate. A package substrate may comprise any suitable type of substrate capable of providing electrical communications between a die, such as an integrated circuit (IC) die, and a next-level component to which an microelectronic package may be coupled (e.g., a circuit board). In another embodiment, the substrate may comprise any suitable type of substrate capable of providing electrical communication between an IC die and an upper IC package coupled with a lower IC/die package, and in a further embodiment a substrate may comprise any suitable type of substrate capable of providing electrical communication between an upper IC package and a next-level component to which an IC package is coupled.

A substrate may also provide structural support for a die/device. By way of example, in one embodiment, a substrate may comprise a multi-layer substrate—including alternating layers of a dielectric material and metal—built-up around a core layer (either a dielectric or a metal core). In another embodiment, a substrate may comprise a coreless multi-layer substrate. Other types of substrates and substrate materials may also find use with the disclosed embodiments (e.g., ceramics, sapphire, glass, etc.). Further, according to one embodiment, a substrate may comprise alternating layers of dielectric material and metal that are built-up over a die itself—this process is sometimes referred to as a “bumpless build-up process.” Where such an approach is utilized, conductive interconnects may or may not be needed (as the build-up layers may be disposed directly over a die, in some cases).

A die/device may comprise any type of integrated circuit device. In one embodiment, the die may include a processing system (either single core or multi-core). For example, the die may comprise a microprocessor, a graphics processor, a signal processor, a network processor, a chipset, etc. In one embodiment, a die may comprise a system-on-chip (SoC) having multiple functional units (e.g., one or more processing units, one or more graphics units, one or more communications units, one or more signal processing units, one or more security units, etc.). However, it should be understood that the disclosed embodiments are not limited to any particular type or class of devices/die.

Conductive interconnect structures may be disposed on a side(s) of a die/device, and may comprise any type of structure and materials capable of providing electrical communication between a die/device and a substrate, or another die/device, for example. In an embodiment, conductive interconnect structures may comprise an electrically conductive terminal on a die (e.g., a pad, bump, stud bump, column, pillar, or other suitable structure or combination of structures) and a corresponding electrically conductive terminal on a substrate (e.g., a pad, bump, stud bump, column, pillar, or other suitable structure or combination of structures). Solder (e.g., in the form of balls or bumps) may be disposed on the terminals of the substrate and/or die/device, and these terminals may then be joined using a solder reflow process. Of course, it should be understood that many other types of interconnects and materials are possible (e.g., wirebonds extending between a die and a substrate).

The terminals on a die may comprise any suitable material or any suitable combination of materials, whether disposed in multiple layers or combined to form one or more alloys and/or one or more intermetallic compounds. For example, the terminals on a die may include copper, aluminum, gold, silver, nickel, titanium, tungsten, as well as any combination of these and/or other metals. In other embodiments, a terminal may comprise one or more non-metallic materials (e.g., a conductive polymer). The terminals on a substrate may also comprise any suitable material or any suitable combination of materials, whether disposed in multiple layers or combined to form one or more alloys and/or one or more intermetallic compounds.

For example, the terminals on a substrate may include copper, aluminum, gold, silver, nickel, titanium, tungsten, as well as any combination of these and/or other metals. Any suitable solder material may be used to join the mating terminals of the die and substrate, respectively. For example, the solder material may comprise any one or more of tin, copper, silver, gold, lead, nickel, indium, as well as any combination of these and/or other metals. The solder may also include one or more additives and/or filler materials to alter a characteristic of the solder (e.g., to alter a reflow temperature).

Embodiments of methods of forming packaging structures, such as methods of forming an interposer comprising openings for capillary underfill, are described. Those methods/structures may include a first substrate comprising a first die, wherein an underfill material is disposed on a first surface of the first substrate adjacent the first die; and a second substrate disposed on the first substrate, wherein the second substrate comprises at least one opening disposed over the first die, wherein the at least one opening is at least partially filled with the underfill material. The embodiments herein improve solder joint reliability for package structures, such as system on chip (SOC) POP package assemblies.

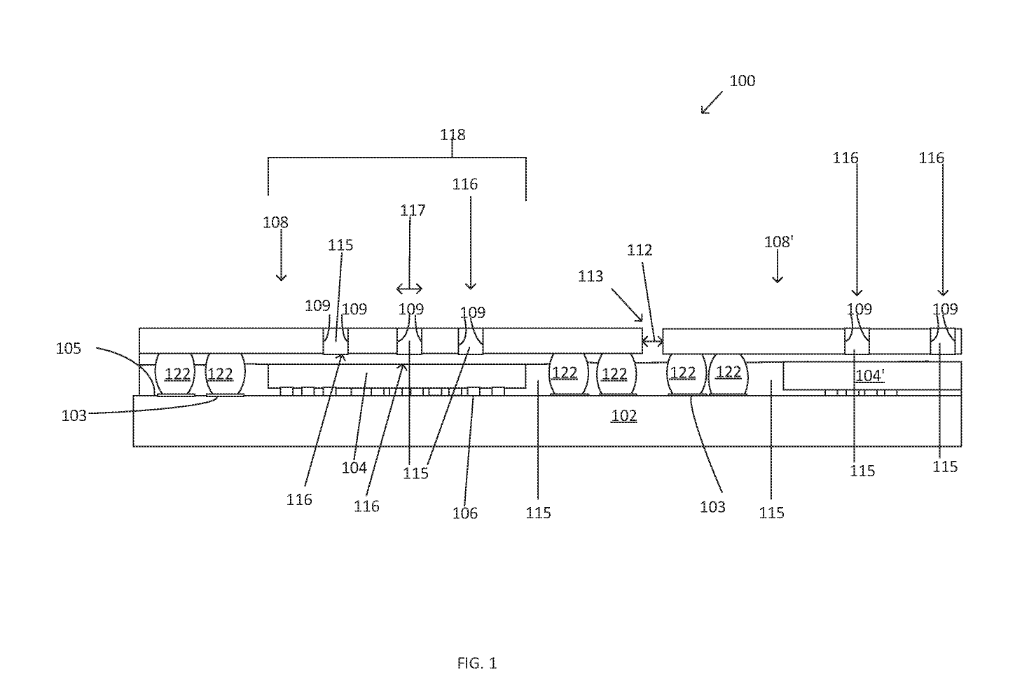

FIG. 1 illustrates an embodiment of a package structure comprising an interposer with at least one opening. In FIG. 1 (cross-sectional view), a portion of a package structure 100, which may comprise a portion of a package on package (PoP) assembly, may include a first substrate 102. The first substrate 102 may comprise alternating layers of dielectric and conductive material/layers (not shown), which may comprise routing signals, such as 10 signals, Vss and Vcc power planes, for example. The dielectric materials of the first substrate 102 may comprise such materials as bismaleimine triazine resin, fire retardant grade 4 material, polyimide materials, glass reinforced epoxy matrix material, and the like, as well as laminates or multiple layers thereof. The microelectronic first substrate 102 conductive routes may be composed of any conductive material, including but not limited to metals, such as copper and aluminum, and alloys thereof. In an embodiment, the first substrate 102 may comprise a substrate panel, wherein a number of die may be disposed on the substrate panel, and wherein portions of the substrate may be subsequently partitioned into individual portions comprising an individual die, during an assembly process, for example.

The first substrate 102 may further comprise at least one die 104 disposed on the first surface of the first substrate 102. The at least one die may 104 comprise any suitable type of die, such as a such as a microprocessor, a chipset, a graphics device, a wireless device, a memory device, an application specific integrated circuit, or the like, and may be attached to a first surface 105 of the first substrate 102. through a plurality of conductive interconnects 106 in a configuration generally known as a flip-chip or controlled collapse chip connection (“C4”) configuration. The conductive interconnects 106 may extend between interconnection pads (not shown) disposed on an active surface of the microelectronic device 104 and interconnection pads (not shown) disposed on the first side 105 of the first substrate/substrate panel 102.

Solder interconnect structures 122 which may comprise through mold interconnect (TMI) structures 122, may be located adjacent individual die disposed on the first substrate 102, and may be disposed on contact structures 103 disposed on the first side 105 of the first substrate 102. The at least one die/device 104 may comprise a system on a chip device, for example, and each individual die 104 may be disposed between the solder interconnect structures 122. An underfill material 115, such as an epoxy underfill material, may be disposed adjacent the at least one die 104 and the solder interconnect structures 122, and on the first surface of the first substrate 102.

A second substrate 108 may be disposed on the first substrate 102, and may comprise an interposer, for example. The second substrate 108 may comprise any suitable type of substrate materials/signal routing, such as conductive traces disposed within dielectric material. The second substrate 108 may comprise a series of discontinuities/openings 116, wherein the discontinuities 116 may be at least partially filled with the epoxy underfill compound 115. The openings 116 may comprise sidewalls adjacent the underfill material 115 disposed at least partially within the openings 116.

The opening 116 may comprise a height that is about the same height of the second substrate 108, in an embodiment, wherein a height of the interposer may comprise between about 50 microns to about 300 microns. In an embodiment. The opening 116 may comprise a width 117 of between about 100 microns to about 1000 microns in an embodiment. The width 117 of the opening 116 may vary according to the particular design requirements. A gap 112 may be disposed between adjacent second substrates 108, 108′. The adjacent second substrates 108, 108′ may be disposed over adjacent die 104, 104′ respectively. The gap 112 may comprise a width 112 of about 120 microns to about 180 microns, in an embodiment. The openings 116 aid in the dispensing of the underfill material during assembly processing, as will be described further herein. In an embodiment, the openings 116 are formed in regions of the second substrate where signal routing/conductive traces is/are not located, and are located within the footprint 118 of the die 104. By using the openings/vents holes 116, the gap width 112 is greatly reduced during an underfill dispense process.

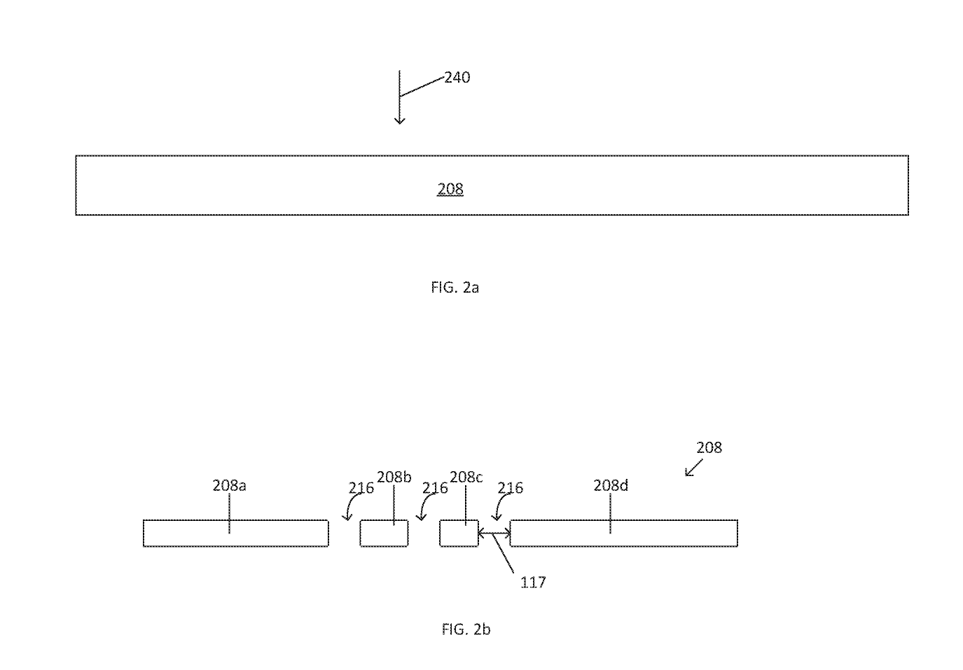

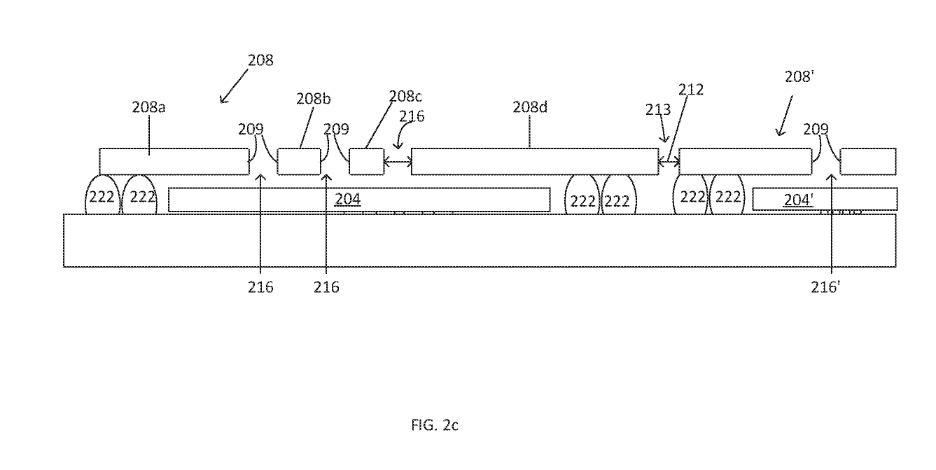

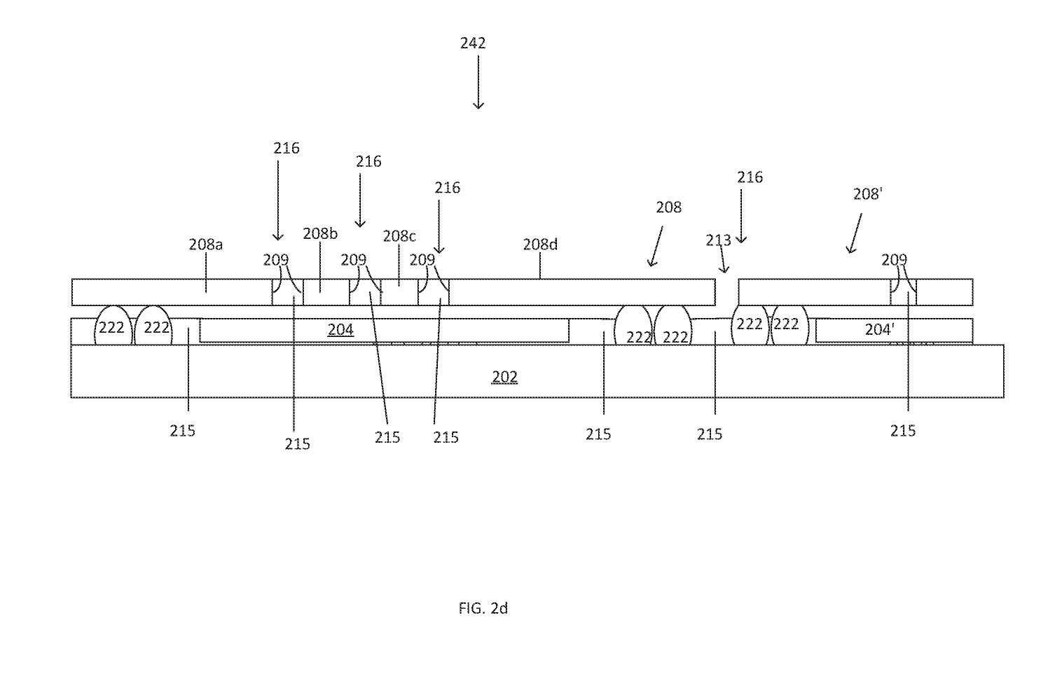

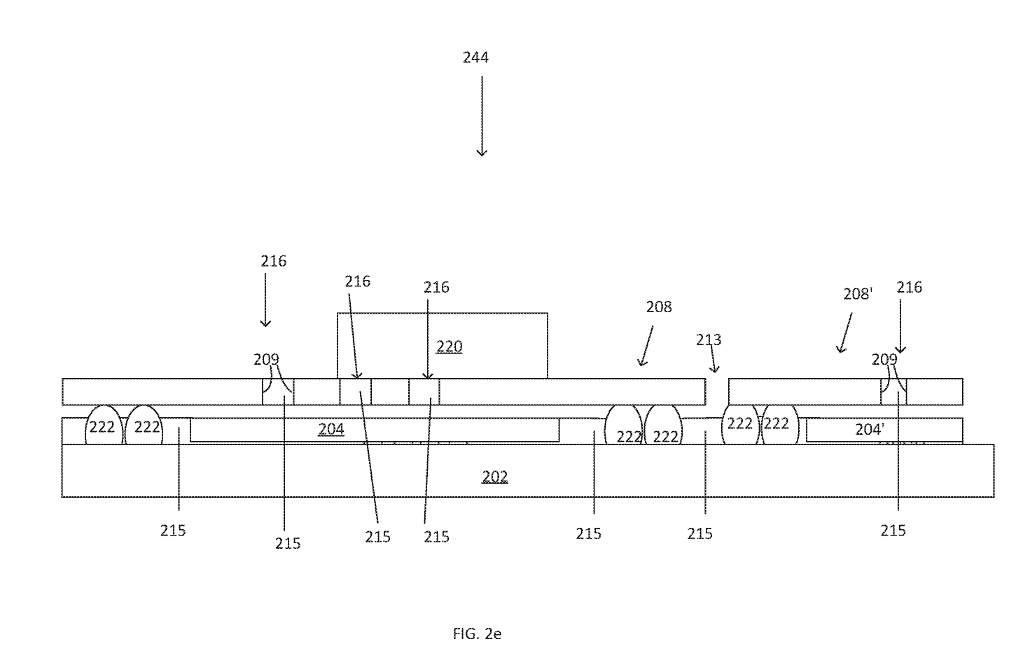

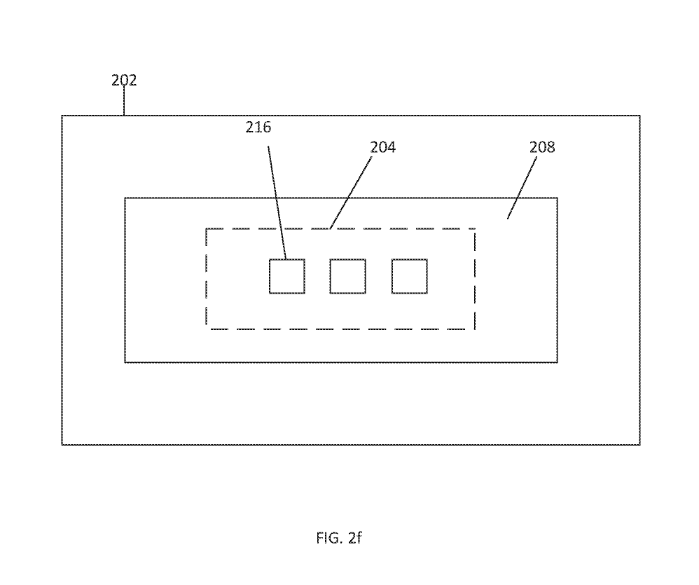

FIGS. 2a-2f depict cross sectional views of methods of forming package structures according to embodiments. In FIGS. 2a-2b, a substrate 208, such as the second substrate 108 of FIG. 1, may be provided. A removal process 240, such as a laser drill process 240, for example, may be employed to form openings 216 in the second substrate 208 (FIG. 2b), wherein the openings 216 may comprise sidewalls 209. The number of openings 216 formed may vary depending upon the particular application, and may vary depending upon thermal considerations of devices to be assembled/coupled to the substrate 208. A width 217 of the openings 216 may comprise between about 100 to about 1000 microns, in an embodiment. The sidewalls of the openings may comprise various angles/shapes, and may comprise non-vertical sidewalls, in some embodiments. In an embodiment, the openings 216 may comprise a circular shape, or a rectangular shape (as viewed from a top view), or any other suitable shape, for example.

At least one substrate/interposer 208 may be placed, by an attachment process, for example, onto a lower substrate 202, similar to the first substrate 102 of FIG. 1, wherein two substrate/interposers 208, 208′ are depicted for simplicity (FIG. 2c). The lower substrate 202 may comprise a substrate panel, wherein a plurality of die 204 (die 204, 204′ are shown for simplicity) may be disposed thereon. In an embodiment, the at least one die 204, 204′ may comprise a central processing unit (CPU), for example and/or a portion of a system on a chip, for example. The die 204, 204′ may be disposed adjacent and in between solder interconnect structures 222, which may comprise TMI interconnect structures 222, in an embodiment. A gap 213 is disposed between the two substrates/interposers 208, 208′, wherein the gap comprises a width 212 of between about 130 to about 180 microns, in an embodiment. The openings 216 of the substrate 208 may be located within the footprint of the die 204, in an embodiment.

An underfill material 215 may be dispensed utilizing a dispense process 242, wherein the dispense process 242 may comprise a capillary underfill dispense process, in an embodiment (FIG. 2d). Because the substrates 208, 208′ comprise at least one opening 216 in addition to the gap 213 between the substrates 208, 208′, the underfill 215 may be more evenly dispensed between the die 104, 104′, the TMI structures 222, and between the substrates 208, 208′ and the lower substrate 202. By having multiple openings through which to dispense the underfill material 215, warpage and voids are greatly diminished or eliminated.

Solder joint reliability is improved consequently. The openings 216 located within the substrate/interposer 208 of the embodiments herein prevent voiding trapping, since the underfill material 215 tends to flow from the center of the interposer 208 initially, then subsequently flows towards outer regions of the interposer/substrate 208. The dispense process 242 tends to fill the volume underneath the first interposer 208 before merging/flowing towards an adjacent interposer 208′ on the substrate panel 202. The substrate/interposer structures included herein tend to allow underfill material to flow in towards the center of the substrate/interposer 208, wherein air can then escape through the openings 216.

FIG. 2e depicts a cross-sectional view of an embodiment in which a second die 220 is attached, by a die attach process 244, to the substrate/interposer 208. The second die 220 may comprise a memory die, in an embodiment, but may also comprise any suitable type of die, according the particular application. In some embodiments, multiple die and/or a plurality of stacked die may be disposed on the substrate 208. In an embodiment, the second die 220 may be at least partially on/over the openings 216 of the interposer 208. In an embodiment, the second die 220 may be placed wherein any hot spots of the second die 220 may not be disposed between sidewall portions 209 of the substrate sections 208a-208d, since the underfill material 215 located within the openings 216 may exacerbate thermal issues at the hot spot locations of the second die 220. FIG. 2f depicts a top view of the substrate 208, wherein the openings 216 are disposed within the footprint of the die 204 located on the lower substrate 202.

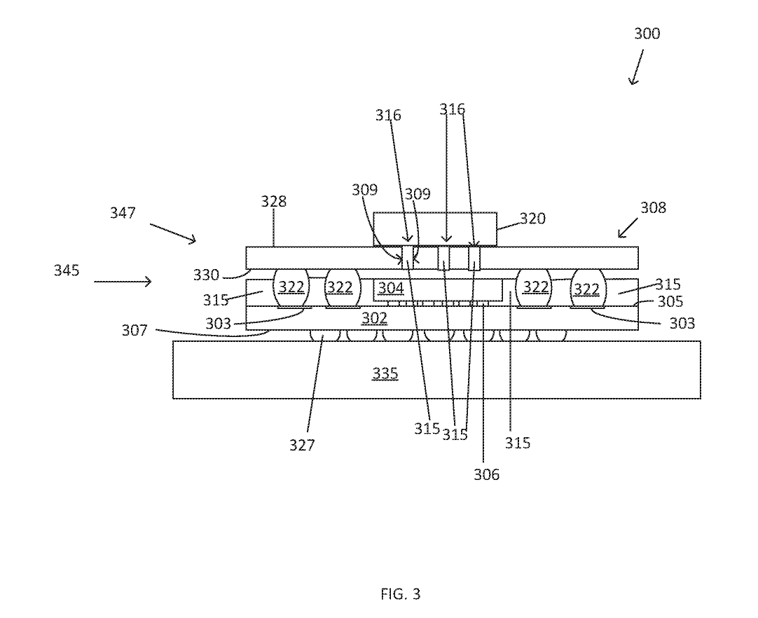

FIG. 3 depicts an embodiment of a package assembly 300. In an embodiment, the package assembly 300 may comprise a lower/first package 345 that may comprise a first die 304 disposed on a first side 305 of a first substrate 302. The first package 345 may be attached/disposed on an upper/second package 347, wherein the upper package 347 may comprise a second die 320 disposed on a first side 328 of the upper/second substrate 308. In an embodiment, the second/upper substrate 308 may comprise discontinuities/openings 316 comprising sidewalls 309, wherein the openings 316 are at least partially filled with an underfill material 315. The openings 316 may comprise a width of about 100 microns to about 1000 microns, in an embodiment, and may comprise any suitable shape, such as a rectangular or a circular shape, for example. In an embodiment, the openings 316 may be disposed within a footprint of the first die 304.

In an embodiment, solder balls/solder joints 322 may be disposed on both the conductive contact pads 303 disposed a first side 305 of the first substrate 302 and on a second side 330 of the second substrate 308, and may electrically and physically couple the second substrate 308 to the first substrate 302. The solder balls 322 may have been formed by undergoing a previous attachment/reflow process, such as a surface mount technology process (SMT) for example, wherein the solder balls 322 have undergone temperature cycling at above about 200 degrees Celsius, to form the solder joints 322 between the first and second packages 302, 308. The underfill material 315 may be disposed adjacent the solder structures 322, and adjacent the die 304, and may be disposed on the first side 305 of the first substrate 302.

A board 335, such as a motherboard, may be attached to a lower substrate 302 of the package assembly 300, subsequent to partitioning a substrate panel, such as the first substrate 202 panel of FIG. 2e, for example, into separate packages. A plurality of solder interconnects 327 may be disposed between the board 335 and a second side 337 of the lower/first substrate 302. The joined first and second packages 302, 308 may comprise a package on package (POP) assembly 300. In an embodiment, the second die 320 may be disposed on/over the first die 304.

The first die 304, may comprise a system on a chip, or a central processing unit (CPU), for example, but may comprise any other suitable type of die. In an embodiment, the solder balls 322 may comprise through mold interconnect (TMI) solder balls 322. The package structure 300 of FIG. 3 exhibits reduced warpage and voiding due to the openings 316 which provide a more even dispensing of the underfill material 315 during previous capillary underfill processing

The board 335 may comprise any suitable type of circuit board or other substrate capable of providing electrical communication between one or more of the various components disposed on the board 335. In one embodiment, for example, the board 335 may comprise a printed circuit board (PCB) comprising multiple metal layers separated from one another by a layer of dielectric material and interconnected by electrically conductive vias. Any one or more of the metal layers may be formed in a desired circuit pattern to route—perhaps in conjunction with other metal layers—electrical signals between the components coupled with the board 335. However, it should be understood that the disclosed embodiments are not limited to the above-described PCB and, further, that board 335 may comprise any other suitable substrate.

The PoP assembly 300 includes the first package 345 and the second package 347, wherein each of the first and second packages 345, 347 may include any suitable device/die or combination of devices. According to one embodiment, first package 345 includes one or more processing systems and the second package 347 includes one or more memory devices. In another embodiment, first package 345 includes one or more processing systems and the second package 347 comprises a wireless communications system (or, alternatively, includes one or more components of a communications system).

In a further embodiment, the first package 345 includes one or more processing systems and the second package 347 includes a graphics processing system. The PoP assembly 300 may comprise part of any type of computing system, such as a hand-held computing system (e.g., a cell phone, smart phone, music player, etc.), mobile computing system (e.g., a laptop, nettop, tablet, etc.), a desktop computing system, or a server. In one embodiment, the PoP assembly 300 comprises a solid-state drive (SSD).

The embodiments described herein provide substrate/Interposer structures for such as package architectures as POP package assemblies, for example, which enabling void free adhesive capillary underfill processing. Warpage is reduced, and thermal properties and solder joint reliability are significantly improved. The gap between adjacent substrates/interposers on a panel structure is greatly reduced, thus increasing process throughput. The openings located within the substrate/interposer of the embodiments herein prevent voiding trapping, since the underfill material flows from the center of the interposer towards the outer regions of the interposer, and fills the volume underneath the first interposer before merging with an adjacent interposer on a panel. The number and size of the substrate/interposer openings may be optimized for a particular application. Dispense rates may be increased by using the embodiments herein, and the location of the openings may be placed in areas of the substrate/interposer where routing layers are avoided.

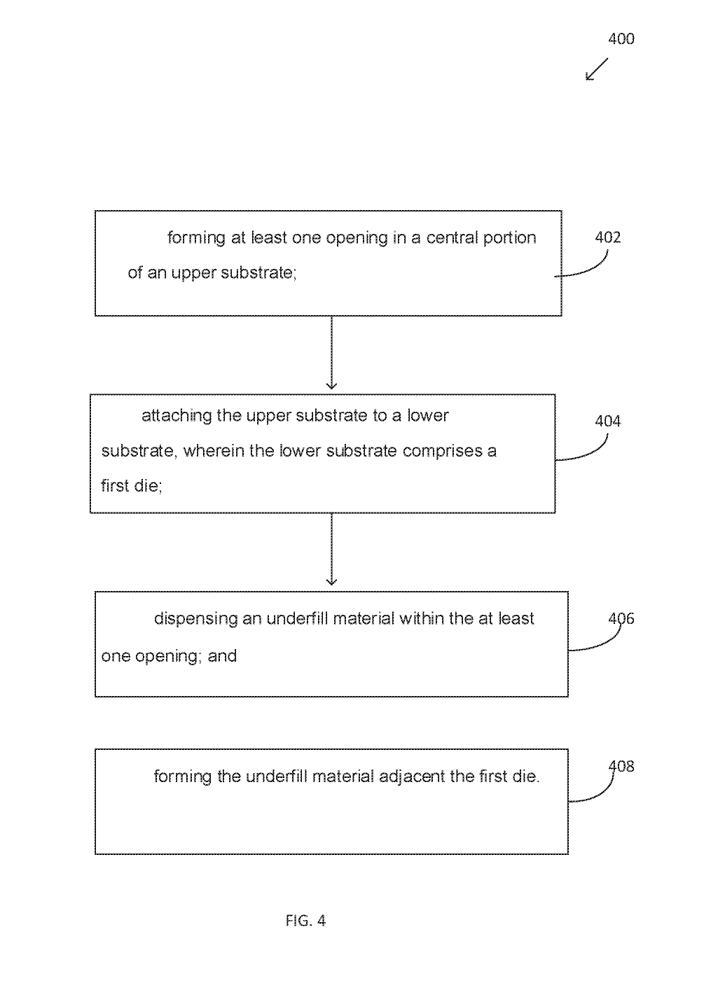

FIG. 4 depicts a method 400 according to embodiments herein. At step 402, at least one opening may be formed in a central portion of an upper substrate. The at least one substrate 402 may comprise an interposer of an upper POP package, in an embodiment. The at least one opening may comprise a width of about 100 microns to about 1000 microns, in an embodiment, and in other embodiments, the at least one opening may comprise a width/diameter of about 0.9 mm to about 1.1 mm. At step 404, the upper substrate may be attached to a lower substrate, wherein the lower substrate comprises a first die. In an embodiment, the lower substrate may comprise a lower package of a POP package. At step 406, an underfill material may be dispensed within the at least one opening. In an embodiment, the underfill material may be dispensed utilizing a capillary underfill process. At step 408 the underfill material may be formed adjacent the first die. In an embodiment, the underfill material may be at least partially formed within the at least one opening. In an embodiment, the underfill material may additionally be dispensed within a gap located between adjacent interposers disposed on the lower substrate, wherein the gap may comprise a width of about 120 microns to about 180 microns.

The structures of the embodiments herein may be coupled with any suitable type of structures capable of providing electrical communications between a microelectronic device, such as a die, disposed in package structures, and a next-level component to which the package structures may be coupled (e.g., a circuit board). The device/package structures, and the components thereof, of the embodiments herein may comprise circuitry elements such as logic circuitry for use in a processor die, for example. Metallization layers and insulating material may be included in the structures herein, as well as conductive contacts/bumps that may couple metal layers/interconnects to external devices/layers. In some embodiments the structures may further comprise a plurality of dies, which may be stacked upon one another, depending upon the particular embodiment. In an embodiment, the die(s) may be partially or fully embedded in a package structure.

The various embodiments of the device structures included herein may be used for system on a chip (SOC) products, and may find application in such devices as smart phones, notebooks, tablets, wearable devices and other electronic mobile devices. In various implementations, the package structures may be included in a laptop, a netbook, an ultrabook, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder, and wearable devices. In further implementations, the package devices herein may be included in any other electronic devices that process data.

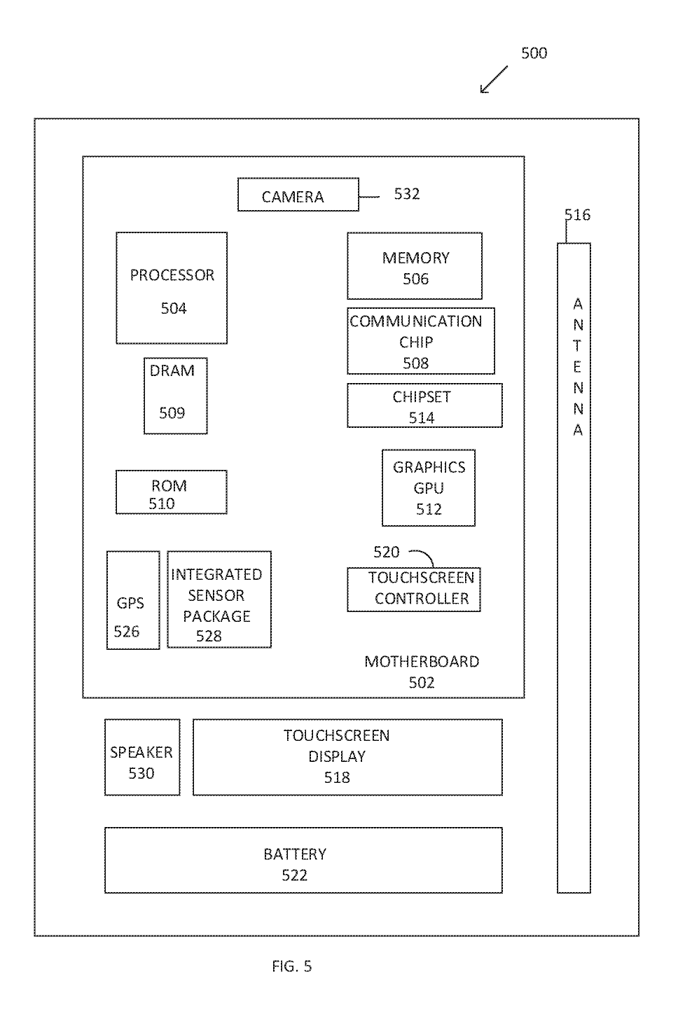

FIG. 5 is a schematic of a computing device 500 that may be implemented incorporating embodiments of the package structures described herein. For example, any suitable ones of the components of the computing device 500 may include, or be included in, package structures/assemblies, such as is depicted in FIG. 3, wherein the an interposer/substrate of an upper package of a POP assembly comprises a plurality of openings. In an embodiment, the computing device 500 houses a board 502, such as a motherboard 502 for example. The board 502 may include a number of components, including but not limited to a processor 504, an on-die memory 506, and at least one communication chip 508. The processor 504 may be physically and electrically coupled to the board 502. In some implementations the at least one communication chip 508 may be physically and electrically coupled to the board 502. In further implementations, the communication chip 508 is part of the processor 504.

Depending on its applications, computing device 500 may include other components that may or may not be physically and electrically coupled to the board 502, and may or may not be communicatively coupled to each other. These other components include, but are not limited to, volatile memory (e.g., DRAM) 509, non-volatile memory (e.g., ROM) 510, flash memory (not shown), a graphics processor unit (GPU) 512, a chipset 514, an antenna 516, a display 518 such as a touchscreen display, a touchscreen controller 520, a battery 522, an audio codec (not shown), a video codec (not shown), a global positioning system (GPS) device 526, an integrated sensor 528, a speaker 530, a camera 532, compact disk (CD) (not shown), digital versatile disk (DVD) (not shown), and so forth. These components may be connected to the system board 502, mounted to the system board, or combined with any of the other components.

The communication chip 508 enables wireless and/or wired communications for the transfer of data to and from the computing device 500. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 508 may implement any of a number of wireless or wired standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, Ethernet derivatives thereof, as well as any other wireless and wired protocols that are designated as 3G, 4G, 5G, and beyond.

The computing device 500 may include a plurality of communication chips 508. For instance, a first communication chip may be dedicated to shorter range wireless communications such as Wi-Fi and Bluetooth and a second communication chip may be dedicated to longer range wireless communications such as GPS, EDGE, GPRS, CDMA, WiMAX, LTE, Ev-DO, and others. The term “processor” may refer to any device or portion of a device that processes electronic data from registers and/or memory to transform that electronic data into other electronic data that may be stored in registers and/or memory.

In various implementations, the computing device 500 may be a laptop, a netbook, a notebook, an ultrabook, a smartphone, a tablet, a personal digital assistant (PDA), an ultra mobile PC, a wearable device, a mobile phone, a desktop computer, a server, a printer, a scanner, a monitor, a set-top box, an entertainment control unit, a digital camera, a portable music player, or a digital video recorder. In further implementations, the computing device 500 may be any other electronic device that processes data.

Embodiments of the package structures described herein may be implemented as a part of one or more memory chips, controllers, CPUs (Central Processing Unit), microchips or integrated circuits interconnected using a motherboard, an application specific integrated circuit (ASIC), and/or a field programmable gate array (FPGA).

### EXAMPLES

Example 1 is a microelectronic package structure comprising: a first substrate, a first die disposed on a surface of the substrate, an underfill material disposed on the first surface of the first substrate and adjacent the first die; and a second substrate disposed on the first substrate, wherein the second substrate comprises at least one opening disposed over the first die, wherein the at least one opening is at least partially filled with the underfill material.

Example 2 includes the microelectronic package structure of example 1, wherein the at least one opening comprises a width of between about 100 microns to about 1000 microns.

Example 3 includes the microelectronic package structure of example 1 wherein a die is disposed on the second substrate.

Example 4 includes the microelectronic package structure of example 1 wherein the at least one opening comprises sidewalls of the second substrate adjacent the underfill material.

Example 5 includes the microelectronic package structure of example 1 wherein the at least one opening is disposed within a footprint of the first die.

Example 6 includes the microelectronic package structure of example 1 wherein the second substrate comprises an interposer.

Example 7 includes the microelectronic package structure of example 1 wherein the first die comprises a system on a chip die.

Example 8 includes the microelectronic package structure of example 1 wherein the microelectronic package structure comprises a package on package assembly.

Example 9 is a method of forming a microelectronic package structure comprising: forming at least one opening in a central portion of an upper substrate; attaching the upper package substrate to a lower substrate, wherein the lower substrate comprises a first die; dispensing an underfill material within the at least one opening; and forming the underfill material adjacent the first die.

Example 10 includes the method of forming the microelectronic package structure of example 9 wherein attaching the upper substrate further comprises placing the at least opening within a footprint of the first die.

Example 11 includes the method of forming the microelectronic package structure of example 9 further comprising forming the underfill material adjacent solder joints disposed between the upper substrate and the lower substrate.

Example 12 includes the method of forming the microelectronic package structure of example 9 wherein forming the at least one opening comprises laser drilling the at least one opening.

Example 13 includes the method of forming the microelectronic package structure of example 9 wherein the lower substrate comprises a plurality of die disposed on a first side of the lower substrate.

Example 14 includes the method of forming the microelectronic package structure of example 13 further comprising placing an additional upper substrate on the lower substrate, and dispensing the underfill material in a gap between the upper substrate and the additional upper substrate.

Example 15 includes the method of forming the microelectronic package structure of example 14 wherein the gap comprises between about 130 microns and about 180 microns.

Example 16 includes the method of forming the microelectronic package structure of example 9, wherein the microelectronic package structure comprises a package on package assembly.

Example 17 is a microelectronic system, comprising: a board; a microelectronic package assembly attached to the board, wherein the microelectronic package comprises: a first substrate; a first die on a surface of the first substrate, wherein an underfill material is disposed on the first surface adjacent the first die; and a second substrate disposed on the first substrate, wherein the second substrate comprises at least one opening over the first die, and wherein the at least one opening is at least partially filled with the underfill material.

Example 18 includes the microelectronic system of example 17 wherein the at least one opening is disposed within a footprint of the first die.

Example 19 includes the microelectronic system of example 17 wherein the at least one opening comprises a width of between about 100 microns to about 1000 microns.

Example 20 includes the microelectronic system of example 17 wherein a depth of the opening is equal to a height of the second substrate.

Example 21 includes the microelectronic system of example 17 wherein at least one solder structure is disposed between the first substrate and the second substrate in a peripheral portion of the first substrate, and wherein the underfill material is adjacent the at least one solder structure.

Example 22 includes the microelectronic system of example 17 wherein the second substrate comprises a second die disposed on a surface of the second substrate.

Example 23 includes the microelectronic system of example 22 wherein the second die is disposed at least partially over at least one of the at least one openings.

Example 24 includes the microelectronic package system of example 17 wherein the first die comprises a system on a chip.

Example 25 includes the microelectronic system of example 17 wherein the microelectronic package assembly comprises a package on package assembly.

Although the foregoing description has specified certain steps and materials that may be used in the methods of the embodiments, those skilled in the art will appreciate that many modifications and substitutions may be made. Accordingly, it is intended that all such modifications, alterations, substitutions and additions be considered to fall within the spirit and scope of the embodiments as defined by the appended claims. In addition, the Figures provided herein illustrate only portions of exemplary microelectronic devices and associated package structures that pertain to the practice of the embodiments. Thus, the embodiments are not limited to the structures described herein.

1. A microelectronic package structure comprising:
a first substrate;
a first die on a surface of the first substrate;
an underfill material on the surface of the first substrate adjacent the first die;
a second substrate over the first die, wherein the second substrate comprises at least one opening, wherein the at least one opening is within a footprint of the first die, and wherein the at least one opening is at least partially filled with the underfill material; and
a second die on the second substrate and over the at least one opening.

2. The microelectronic package structure of claim 1, wherein a width of the at least one opening comprises between about 30 microns to about 1000 microns.

3. The microelectronic package structure of claim 1 wherein the at least one opening is within the footprint of the second die.

4. The microelectronic package structure of claim 1 wherein the second substrate comprises an interposer, and wherein the underfill substantially fills the at least one opening.

5. The microelectronic package structure of claim 1 wherein the second die is on a first side of the second substrate, and wherein a gap is between a top surface of the first die and a second side of the second substrate, wherein the second side is opposite the first side.

6. The microelectronic package structure of claim 1 wherein a portion of the underfill comprises a surface, wherein the surface is coplanar with a top surface of the first die.

7. The microelectronic package structure of claim 1 wherein the die comprises a system on a chip die.

8. The microelectronic package structure of claim 1 wherein the microelectronic package structure comprises a package on package assembly.

9. A method of forming a microelectronic package structure comprising:
forming at least one opening in a central portion of an upper substrate;
attaching the upper substrate to a lower substrate, wherein the lower substrate comprises a first die on a surface of the lower substrate;
dispensing an underfill material within the at least one opening, wherein the at least one opening is at least partially filled with the underfill material;
forming the underfill material adjacent the first die;
attaching a second die on the upper substrate, wherein the at least one opening is within a footprint of the second die.

10. The method of forming the microelectronic package structure of claim 9 wherein attaching the upper substrate further comprises placing the at least opening within a footprint of the first die.

11. The method of forming the microelectronic package structure of claim 9 further comprising forming the underfill material adjacent solder joints between the upper substrate and the lower substrate.

12. The method of forming the microelectronic package structure of claim 9 wherein forming the at least one opening comprises laser drilling the at least one opening.

13. The method of forming the microelectronic package structure of claim 9 wherein the lower substrate comprises a plurality of die on a first side of the lower substrate.

14. The method of forming the microelectronic package structure of claim 13 further comprising dispensing the underfill material in a gap between the upper substrate and the lower substrate.

15. The method of forming the microelectronic package structure of claim 14 wherein the gap comprises a width of between about 130 microns and about 180 microns.

16. The method of forming the microelectronic package structure of claim 9, wherein the microelectronic package structure comprises a package on package assembly.

17. A microelectronic system, comprising:
a board;
a microelectronic package assembly attached to the board, wherein the microelectronic package comprises:
a first substrate;
a die on the first substrate, wherein an underfill material is on a first surface of the first substrate adjacent the die; and
a second substrate over the first die, wherein the second substrate comprises at least one opening over the die, and wherein the at least one opening is at least partially filled with the underfill material, and wherein the at least one opening is within a footprint of the first die.

18. The microelectronic system of claim 17, wherein the die comprises a first die, and further comprising a second die on the second substrate, wherein the at least one opening is within a footprint of the second die.

19. The microelectronic system of claim 17 wherein the at least one opening comprises a width of between about 100 microns to about 1000 microns.

20. The microelectronic system of claim 17 wherein a depth of the at least one opening is equal to a height of the second substrate.

21. The microelectronic system of claim 17 wherein at least one solder structure is between the first substrate and the second substrate in a peripheral portion of the first substrate, and wherein a portion of the underfill material is adjacent the at least one solder structure, and wherein a surface of the portion of the underfill material is coplanar with a top surface of the first die.

22. The microelectronic system of claim 21 wherein a height of the solder structure is above the surface of the portion of the underfill material.

23. The microelectronic system of claim 17 wherein the at least one opening is substantially filled with the underfill material.

24. The microelectronic package system of claim 17 wherein the die comprises a system on a chip.

25. The microelectronic system of claim 17 wherein the microelectronic package assembly comprises a package on package assembly.
